(19) United States
(12) Patent Application Publication
(10) Pub. No.: US 2026/0025137 A1
(43) Pub. Date: Jan. 22, 2026

(54) SEMICONDUCTOR DEVICE AND OPERATING METHOD OF THE SEMICONDUCTOR DEVICE

(71) Applicant: SK hynix Inc., Gyeonggi-do (KR)

(72) Inventor: Hyun Chul LEE, Gyeonggi-do (KR)

(21) Appl. No.: 18/963,511

(22) Filed: Nov. 28, 2024

(30) Foreign Application Priority Data
Jul. 17, 2024 (KR) 10-2024-0094544

(51) Int. Cl. H03K 19/00; G11C 5/14; H03K 19/08

(52) U.S. Cl. CPC H03K 19/0016; G11C 5/147; H03K 19/08

(57) ABSTRACT

A semiconductor device includes a first regulator, a logic circuit, and a first transmission circuit. The first regulator generates a first internal voltage. The logic circuit operates using the first internal voltage, and determines an operation mode. The first transmission circuit transmits, using the first internal voltage, an exit command of the first operation mode externally input as a first control signal during the first operation mode to the logic circuit as an internal exit command.

### CROSS-REFERENCES TO RELATED APPLICATION

The present application claims priority under 35 U.S.C. § 119(a) to Korean application number 10-2024-0094544 filed on Jul. 17, 2024, which is incorporated herein by reference in its entirety.

### BACKGROUND

### 1. Technical Field

Various embodiments of the present disclosure generally relate to a semiconductor device.

### 2. Related Art

Semiconductor devices are core components of electronic devices and have a wide range of modern applications, for example, in technologies such as computing, communications, artificial intelligence, and memory. Semiconductor devices may consist of transistors, diodes, integrated circuits (ICs), etc.

Semiconductor devices are evolving to become smaller and faster as technology advances. Along with this, leakage current from transistors in semiconductor devices is becoming an important issue. Leakage current can increase power consumption of a semiconductor device and cause a decrease in power efficiency. Therefore, it may be necessary to develop technologies to minimize leakage current to increase the performance and efficiency of semiconductor devices.

### SUMMARY

In an embodiment of the present disclosure, a semiconductor device may include a first regulator, a logic circuit, and a first transmission circuit. The first regulator may generate a first internal voltage. The logic circuit may be configured to operate using the first internal voltage, and may determine an operation mode. The first transmission circuit may transmit, using the first internal voltage, an exit command of the first operation mode externally input as a first control signal during the first operation mode to the logic circuit as an internal exit command.

In an embodiment, a semiconductor device may include a first regulator, a second regulator, a logic circuit, and a transmission circuit. The first regulator may generate a first internal voltage. The second regulator may generate a second internal voltage. The logic circuit may operate using the first internal voltage, and turn off the second regulator in a first operation mode. The transmission circuit may transmit, using the second internal voltage, a control signal externally input during a second operation mode to the logic circuit as a logic control signal.

In an embodiment of the present disclosure, an operating method of a semiconductor device may include transmitting a command instructing entry into a first operation mode to a logic circuit through a first path; entering, by the logic circuit, the first operation mode in response to the command; and transmitting an exit command of the first operation mode through a second path to the logic circuit.

### BRIEF DESCRIPTION OF THE DRAWINGS

FIG. 1 is a block diagram illustrating a semiconductor device according to an embodiment of the present disclosure.

FIG. 2 is a diagram for illustrating how a semiconductor device processes a deep power-down command received in a normal mode according to an embodiment of the present disclosure.

FIG. 3 is a diagram to illustrate how a semiconductor device processes a deep power-down command received in a normal mode according to an embodiment of the present disclosure.

FIG. 4 is a diagram to illustrate how a semiconductor device processes an exit command received in a deep power-down mode according to an embodiment of the present disclosure.

FIG. 5 is a block diagram illustrating a semiconductor device according to an embodiment of the present disclosure.

FIG. 6 is a diagram to illustrate how a semiconductor device processes a deep power-down command received in a normal mode according to an embodiment of the present disclosure.

FIG. 7 is a diagram to illustrate how a semiconductor device processes an exit command received in a deep power-down mode according to an embodiment of the present disclosure.

FIG. 8 is a waveform diagram of an exit command according to an embodiment of the present disclosure.

FIG. 9 is a flowchart illustrating an operation method of a semiconductor device according to an embodiment of the present disclosure.

### DETAILED DESCRIPTION

Various embodiments of the present disclosure can reduce leakage current in a deep power-down mode.

Hereinafter, embodiments of the present disclosure will be described in more detail with reference to the accompanying drawings.

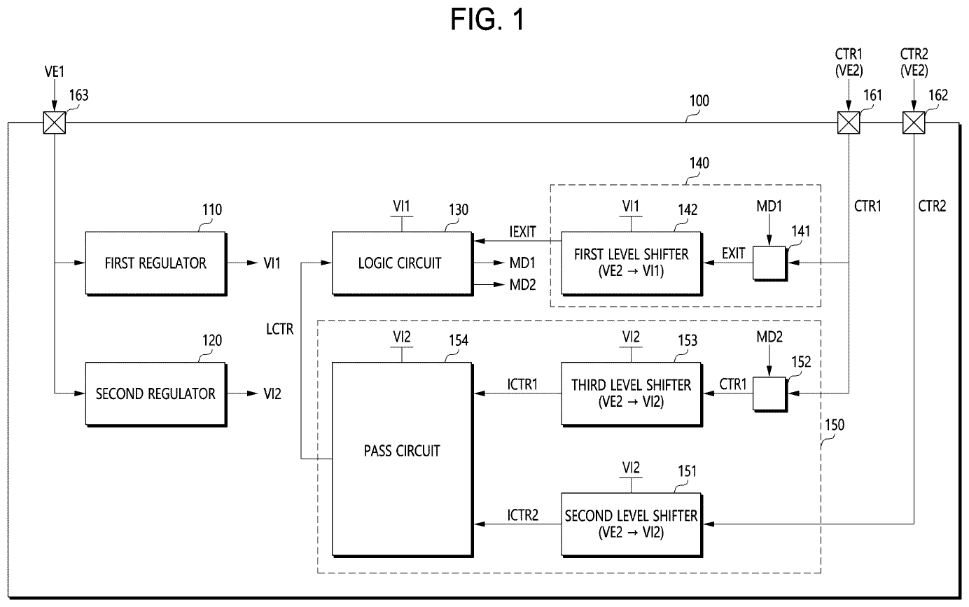

FIG. 1 is a block diagram illustrating a semiconductor device 100 according to an embodiment of the present disclosure.

The semiconductor device 100 may operate in various modes. The operation modes of the semiconductor device 100 may include a normal mode, an idle mode, a sleep mode, a deep power-down mode, and the like. Among these, the deep power-down mode may be an operation mode in which the semiconductor device 100 stops most operations, thereby minimizing power consumption among the operation modes of the semiconductor device 100. The deep power-down mode may be referred to as a first operation mode, and modes other than the deep power-down mode may be referred to as a second operation mode.

Referring to FIG. 1, the semiconductor device 100 may include first to third pads 161 to 163, a first regulator 110, a second regulator 120, a logic circuit 130, a first transmission circuit 140, and a second transmission circuit 150.

The first pad 161 may receive a first control signal CTR1 from an external device (not shown). The first control signal CTR1 may include an exit command EXIT indicating an exit from the deep power-down mode. The first control signal CTR1 may include an operation command instructing an internal operation of the semiconductor device 100, i.e., the first pad 161 may be used to receive an exit command from an external device in the deep power-down mode, and may also be used to receive an operation command from an external device in a predetermined mode other than the deep power-down mode. A logic high level of the first control signal CTR1 received by the first pad 161 may be a second external voltage VE2. The first control signal CTR1 received by the first pad 161 may be transmitted to the first transmission circuit 140 or the second transmission circuit 150.

The second pad 162 may receive a second control signal CTR2 from an external device. The second control signal CTR2 may include an operation command that instructs an internal operation of the semiconductor device 100. The second control signal CTR2 may include a deep power-down command that instructs the semiconductor device 100 to enter a deep power-down mode, i.e., the second pad 162 may be used to receive various commands from an external device in a predetermined mode other than a deep power-down mode. A logic high level of the second control signal CTR2 received by the second pad 162 may be the second external voltage VE2. The second control signal CTR2 received by the second pad 162 may be transmitted to the second transmission circuit 150.

The third pad 163 may receive a first external voltage VE1 from an external device. The first external voltage VE1 received by the third pad 163 may be transmitted to the first regulator 110 and the second regulator 120.

The first regulator 110 may receive the first external voltage VE1 from the third pad 163, and may use the first external voltage VE1 to output a first internal voltage VI1. The first regulator 110 may be, for example, a low voltage step-down regulator. The first regulator 110 may operate in any mode while the semiconductor device 100 is receiving the first external voltage VE1 under control of the logic circuit 130.

The second regulator 120 may receive the first external voltage VE1 from the third pad 163, and may use the first external voltage VE1 to output a second internal voltage VI2. The second regulator 120 may be, for example, a low voltage step-down regulator. The second internal voltage VI2 may be lower than the first internal voltage VI1. The second regulator 120 may be turned off in a deep power-down mode and operated in an operation mode other than the deep power-down mode under control of the logic circuit 130.

In an embodiment, the semiconductor device 100 may further include at least one additional regulator. The additional regulator may, under control of the logic circuit 130, be turned off in a deep power-down mode and operate in an operation mode other than the deep power-down mode, i.e., all regulators other than the first regulator 110 may be turned off in the semiconductor device 100 to minimize power consumption in a deep power-down mode.

For example, when the semiconductor device 100 is a semiconductor memory device, the semiconductor device 100 may further include a third regulator and a data buffer. The third regulator may receive the first external voltage VE1 from the third pad 163, and may output a third internal voltage using the first external voltage VE1. The data buffer may use the third internal voltage to store data. In a deep power-down mode, the second regulator 120 and the third regulator are turned off, which may minimize power consumption of the semiconductor memory device.

The logic circuit 130 may control an operation of the semiconductor device 100 based on a logic control signal LCTR output from the second transmission circuit 150. The logic circuit 130 may operate using the first internal voltage VI1 received from the first regulator 110. Because the first regulator 110 operates in all modes of the semiconductor device 100, the logic circuit 130 may operate using the first internal voltage VI1 in all modes of the semiconductor device 100.

The logic circuit 130 may control an operation mode of the semiconductor device 100 based on predetermined conditions. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. Upon receiving a deep power-down command input from an external device as the logic control signal LCTR, the logic circuit 130 may control the semiconductor device 100 to enter a deep power-down mode. The logic circuit 130 may control the second regulator 120 to turn off (i.e., disable) in a deep power-down mode. The logic circuit 130 may control the semiconductor device 100 to exit the deep power-down mode in response to an internal exit command IEXIT received from the first transmission circuit 140.

The logic circuit 130 may generate a first operation mode signal MD1 and a second operation mode signal MD2 based on an entry/exit to a deep power-down mode. The logic circuit 130 may activate the first operation mode signal MD1 and deactivate the second operation mode signal MD2 while in a deep power-down mode. The logic circuit 130 may deactivate the first operation mode signal MD1 and activate the second operation mode signal MD2 while not in a deep power-down mode. The second operation mode signal MD2 may be an inverted signal of the first operation mode signal MD1.

The first transmission circuit 140 may be coupled to the first pad 161. The first transmission circuit 140 may be enabled in response to the first operation mode signal MD1 received from the logic circuit 130, and may operate using the first internal voltage VI1. Specifically, when an exit command EXIT of a deep power-down mode is transmitted from the first pad 161 as the first control signal CTR1, the first transmission circuit 140 may output the exit command EXIT to the logic circuit 130 as the internal exit command IEXIT in response to the first operation mode signal MD1.

The first transmission circuit 140 may include a first switch 141 and a first level shifter 142.

The first switch 141 may electrically connect the first pad 161 and the first level shifter 142 in response to the first operation mode signal MD1. That is, the first switch 141 may electrically connect the first pad 161 and the first level shifter 142 in a deep power-down mode. Thus, the exit command EXIT received as the first control signal CTR1 in a deep power-down mode may be passed from the first pad 161 to the first level shifter 142 through the first switch 141.

The first level shifter 142 may operate using the first internal voltage VI1. The first level shifter 142 may receive the exit command EXIT whose logic high level is the second external voltage VE2, and may shift a voltage level of the exit command EXIT to output the internal exit command IEXIT whose logic high level is the first internal voltage VI1 to the logic circuit 130.

The second transmission circuit 150 may be coupled to the first pad 161 and the second pad 162. The second transmission circuit 150 may operate using the second internal voltage VI2.

Specifically, the second transmission circuit 150 may receive the second control signal CTR2 from the second pad 162 and output the second control signal CTR2 to the logic circuit 130 as the logic control signal LCTR. When receiving a deep power-down command as the second control signal CTR2 from the second pad 162, the second transmission circuit 150 may output an internal deep power-down command as the logic control signal LCTR to the logic circuit 130.

Further, in response to the second operation mode signal MD2 received from the logic circuit 130, the second transmission circuit 150 may receive the first control signal CTR1 that is not the exit command EXIT from the first pad 161 and output the first control signal CTR1 as the logic control signal LCTR to the logic circuit 130.

The second transmission circuit 150 may include a second level shifter 151, a second switch 152, a third level shifter 153, and a pass circuit 154.

The second level shifter 151 may receive the second control signal CTR2 having a logic high level of the second external voltage VE2, and may shift a voltage level of the second control signal CTR2 to output a second internal control signal ICTR2 having a logic high level of the second internal voltage VI2 to the pass circuit 154.

In response to the second operation mode signal MD2, the second switch 152 may electrically connect the first pad 161 and the third level shifter 153, i.e., the second switch 152 may electrically connect the first pad 161 and the third level shifter 153 in an operation mode other than a deep power-down mode. Thus, in an operation mode other than a deep power-down mode, the first control signal CTR1 other than the exit command EXIT may be transmitted from the first pad 161 to the third level shifter 153 through the second switch 152.

The third level shifter 153 may receive the first control signal CTR1 having a logic high level of the second external voltage VE2, and may shift a voltage level of the first control signal CTR1 to output a first internal control signal ICTR1 having a logic high level of the second internal voltage VI2 to the pass circuit 154.

The second level shifter 151 and the third level shifter 153 may operate using the second internal voltage VI2. The second level shifter 151 and the third level shifter 153 may be turned off by not being supplied with the second internal voltage VI2 in a deep power-down mode.

The pass circuit 154 may output the second internal control signal ICTR2 received from the second level shifter 151 and the first internal control signal ICTR1 received from the third level shifter 153 to the logic circuit 130 as the logic control signal LCTR. The logic control signal LCTR may include an internal deep power-down command.

The pass circuit 154 may include transistors with a thin gate oxide film to operate at high speeds using the second internal voltage VI2 that is lower than the first internal voltage VI1. Such slim transistors have low threshold voltages and may therefore operate based on the second internal voltage VI2, but may generate leakage current. However, because the second regulator 120 is turned off in a deep power-down mode, the pass circuit 154 may be turned off without being supplied with the second internal voltage VI2 in a deep power-down mode. Thus, leakage current in the pass circuit 154 might not occur in a deep power-down mode, and power consumption of the semiconductor device 100 may be minimized. Furthermore, even if the pass circuit 154 does not operate in a deep power-down mode, the logic circuit 130 receives the exit command EXIT of a deep power-down mode through the first transmission circuit 140, so that a deep power-down mode may be preferably terminated.

The semiconductor device 100 may include a semiconductor memory device. A non-volatile semiconductor memory device may include at least one of a NAND Flash memory, a three-dimensional NAND Flash memory, a NOR Flash memory, a resistive random access memory (RRAM), a phase-change memory (PRAM), a magnetoresistive memory (MRAM), a Ferroelectric Random Access Memory (FRAM), and a Spin Transfer Torque Random Access Memory (STT-RAM). A volatile semiconductor memory device may include at least one of a dynamic random access memory (DRAM) and a static random access memory (SRAM).

In an embodiment, in addition to the first pad 161, the semiconductor device 100 may further include at least one additional pad (not shown) for receiving the first control signal CTR1 from an external device. In this case, the first transmission circuit 140 may further include a switch and a level shifter, similar to the first switch 141 and the first level shifter 142, coupled between the additional pad and the logic circuit 130. In addition, the second transmission circuit 150 may further include a switch and a level shifter, similar to the second switch 152 and the third level shifter 153, coupled between the additional pad and the pass circuit 154.

In an embodiment, in addition to the second pad 162, the semiconductor device 100 may further include at least one additional pad (not shown) for receiving the second control signal CTR2 from an external device. In this case, the second transmission circuit 150 may further include a level shifter, similar to the second level shifter 151, coupled between the at least one additional pad and the pass circuit 154.

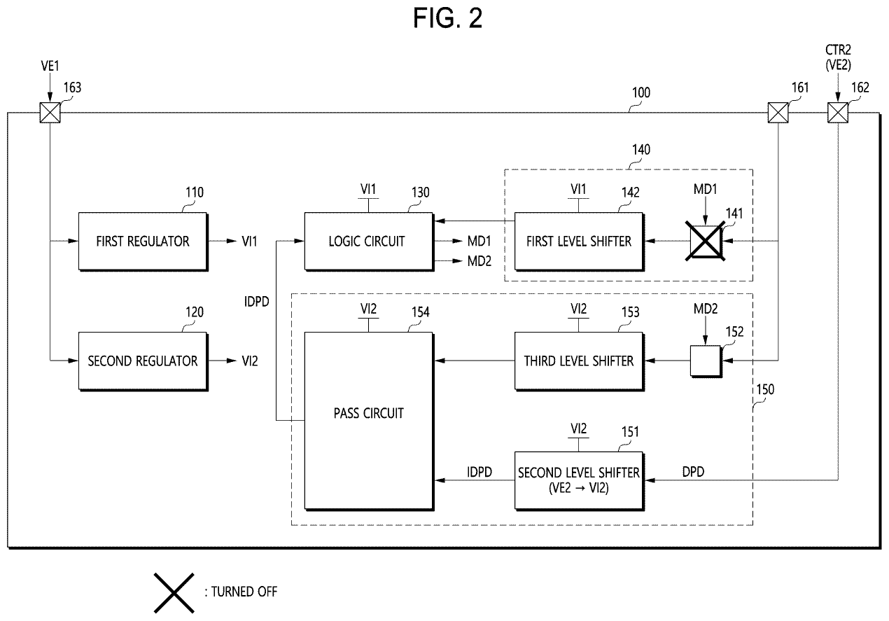

FIG. 2 is a diagram to illustrate how the semiconductor device 100 processes a deep power-down command DPD received in a normal mode according to an embodiment of the present disclosure.

Referring to FIG. 2, in the normal mode, both the first regulator 110 and the second regulator 120 may operate.

In the normal mode, the logic circuit 130 may deactivate the first operation mode signal MD1 and activate the second operation mode signal MD2. Thus, the first switch 141 may be turned off in response to the first operation mode signal MD1 and the second switch 152 may be turned on in response to the second operation mode signal MD2.

The deep power-down command DPD may be input as the second control signal CTR2 through the second pad 162 from an external device. The second level shifter 151 may receive the deep power-down command DPD from the second pad 162 with a logic high level of the second external voltage VE2, and may shift a voltage level of the deep power-down command DPD to output an internal deep power-down command IDPD with a logic high level of the second internal voltage VI2 to the pass circuit 154. The pass circuit 154 may output the internal deep power-down command IDPD received from the second level shifter 151 to the logic circuit 130. In response to the internal deep power-down command IDPD, the logic circuit 130 may control the semiconductor device 100 to enter a deep power-down mode.

In an embodiment, the semiconductor device 100 may receive the deep power-down command DPD from an external device in an operation mode other than the normal mode, and may process the deep power-down command DPD similarly to that described above for the normal mode.

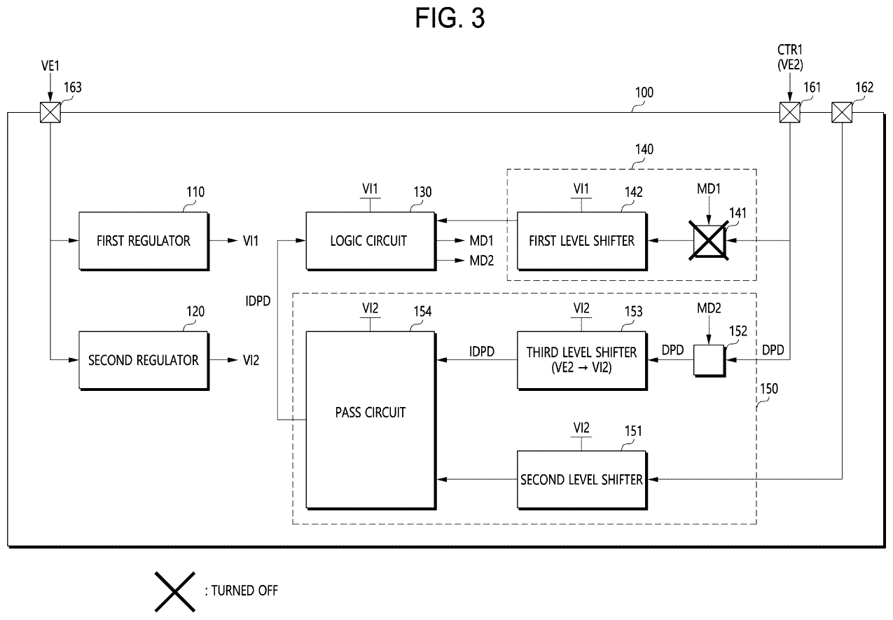

FIG. 3 is a diagram to illustrate how the semiconductor device 100 processes a deep power-down command DPD received in the normal mode according to an embodiment of the present disclosure.

Referring to FIG. 3, the operation of the first regulator 110, the second regulator 120, the first switch 141, and the second switch 152 is as described in FIG. 2.

The deep power-down command DPD may be input as the first control signal CTR1 through the first pad 161 from an external device. In response to the second operation mode signal MD2, the second switch 152 may pass the deep power-down command DPD received from the first pad 161 to the third level shifter 153. The third level shifter 153 may receive the deep power-down command DPD from the second switch 152 with a logic high level of the second external voltage VE2, and may shift a voltage level of the deep power-down command DPD to output the internal deep power-down command IDPD with a logic high level of the second internal voltage VI2 to the pass circuit 154. The pass circuit 154 may output the internal deep power-down command IDPD received from the third level shifter 153 to the logic circuit 130. In response to the internal deep power-down command IDPD, the logic circuit 130 may control the semiconductor device 100 to enter a deep power-down mode.

In the normal mode, when the first pad 161 receives an operation command other than the deep power-down command DPD as the first control signal CTR1, the semiconductor device 100 may process the operation command similar to how it processed the deep power-down command DPD.

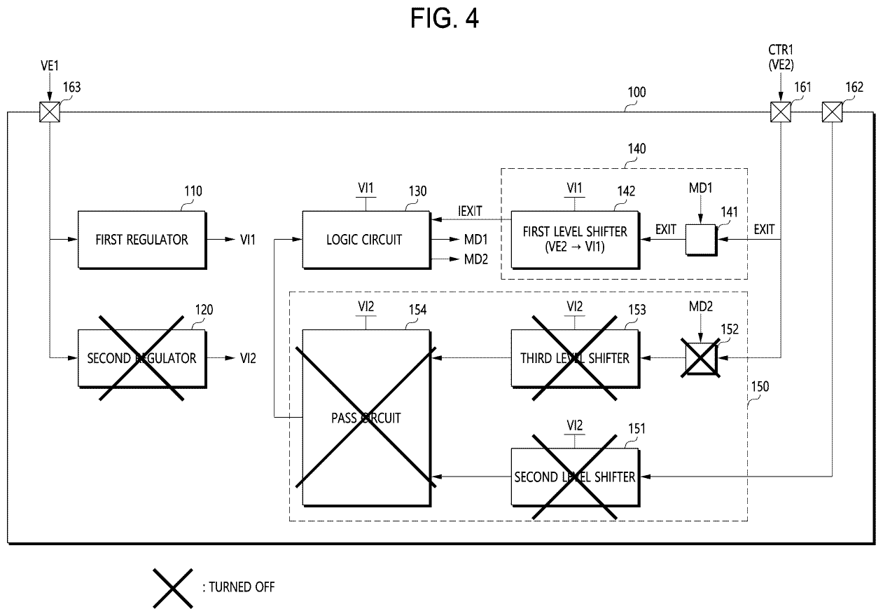

FIG. 4 is a diagram to illustrate how the semiconductor device 100 processes the exit command EXIT received in a deep power-down mode according to an embodiment of the present disclosure.

Referring to FIG. 4, in the deep power-down mode, the second regulator 120 may be turned off. Accordingly, the pass circuit 154, the second level shifter 151, and the third level shifter 153, which are supplied with the second internal voltage VI2, may also be turned off.

The logic circuit 130 may deactivate the second operation mode signal MD2 and activate the first operation mode signal MD1 in the deep power-down mode. Thus, the second switch 152 may be turned off in response to the second operation mode signal MD2 and the first switch 141 may be turned on in response to the first operation mode signal MD1.

In the deep power-down mode, the exit command EXIT may be input as the first control signal CTR1 through the first pad 161 from an external device. In response to the first operation mode signal MD1, the first switch 141 may pass the exit command EXIT received from the first pad 161 to the first level shifter 142. The first level shifter 142 may receive the exit command EXIT from the first switch 141 with a logic high level of the second external voltage VE2, and may shift a voltage level of the exit command EXIT to output the internal exit command IEXIT with a logic high level of the first internal voltage VI1 to the logic circuit 130. In response to the internal exit command IEXIT, the logic circuit 130 may control the semiconductor device 100 to exit the deep power-down mode.

In summary, by turning off the second regulator 120 in the deep power-down mode, the pass circuit 154 might not generate leakage current. And, even if the second transmission circuit 150 including the pass circuit 154 is turned off in the deep power-down mode, the semiconductor device 100 may preferably exit from the deep power-down mode by receiving the exit command EXIT through the first pad 161 and sending it to the logic circuit 130 through the first transmission circuit 140.

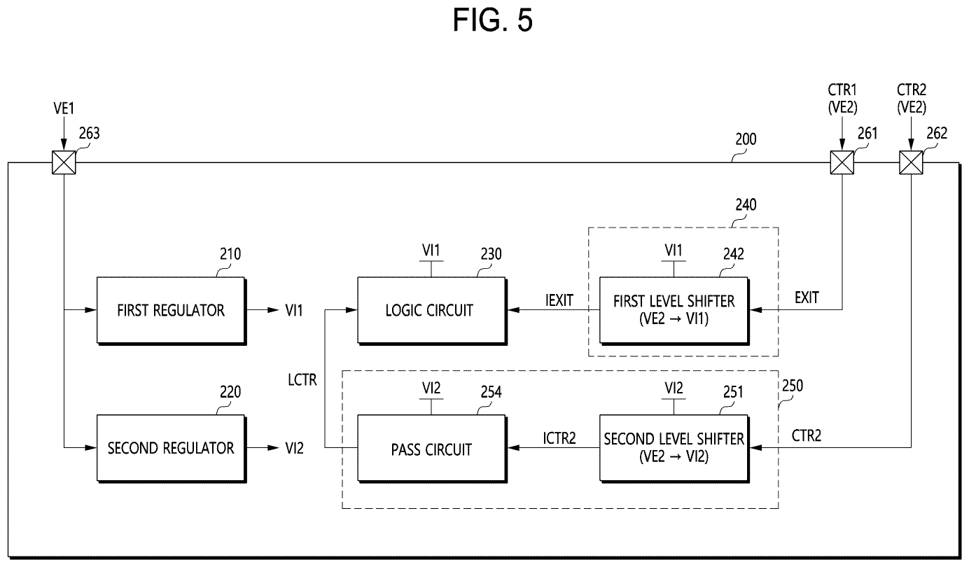

FIG. 5 is a block diagram illustrating a semiconductor device 200 according to an embodiment of the present disclosure.

Referring to FIG. 5, the semiconductor device 200 may include first to third pads 261 to 263, a first regulator 210, a second regulator 220, a logic circuit 230, a first transmission circuit 240, and a second transmission circuit 250. The first transmission circuit 240 may include a first level shifter 242. The second transmission circuit 250 may include a second level shifter 251 and a pass circuit 254. The semiconductor device 200 may be configured and operate similarly to the semiconductor device 100 of FIG. 1, except that it does not include the first switch 141, second switch 152, and third level shifter 153 shown in FIG. 1. The first to third pads 261 to 263, the first regulator 210, the second regulator 220, the logic circuit 230, the first level shifter 242, and the second level shifter 251 may be configured and operated similarly to the first regulator 110, the second regulator 120, the logic circuit 130, the first level shifter 142, and the second level shifter 151 of FIG. 1, respectively.

Specifically, the first pad 261 may receive the first control signal CTR1 from an external device. The first control signal CTR1 may include the exit command EXIT to exit a deep power-down mode. In an embodiment, the first pad 261 may be used only for receiving the exit command EXIT. The exit command EXIT received by the first pad 261 may be transmitted to the first transmission circuit 240.

The first transmission circuit 240 may be coupled to the first pad 261 and may include the first level shifter 242. The first level shifter 242 may receive the exit command EXIT from the first pad 261 with a logic high level of the second external voltage VE2, and may shift a voltage level of the exit command EXIT to output the internal exit command IEXIT with a logic high level of the first internal voltage VI1 to the logic circuit 230.

The second pad 262 may receive the second control signal CTR2 from an external device. The second control signal CTR2 received by the second pad 262 may be transmitted to the second transmission circuit 250.

The second transmission circuit 250 may be coupled to the second pad 262 and may include the second level shifter 251 and the pass circuit 254. The second level shifter 251 may receive the second control signal CTR2 having a logic high level of the second external voltage VE2 from the second pad 262, and may shift a voltage level of the second control signal CTR2 to output the second internal control signal ICTR2 having a logic high level of the second internal voltage VI2 to the pass circuit 254. The pass circuit 254 may output the second internal control signal ICTR2 received from the second level shifter 251 to the logic circuit 230 as the logic control signal LCTR.

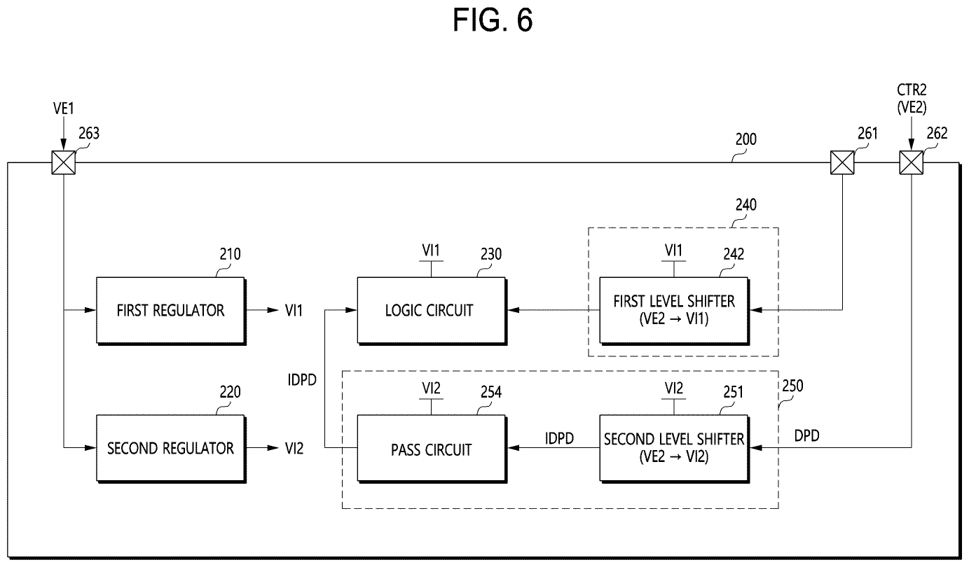

FIG. 6 is a diagram to illustrate how the semiconductor device 200 processes the deep power-down command DPD received in the normal mode according to an embodiment of the present disclosure.

Referring to FIG. 6, in the normal mode, both the first regulator 210 and the second regulator 220 may operate.

The deep power-down command DPD may be input as the second control signal CTR2 through the second pad 262 from an external device. The second level shifter 251 may receive the deep power-down command DPD from the second pad 262 with a logic high level of the second external voltage VE2, and may shift a voltage level of the deep power-down command DPD to output the internal deep power-down command IDPD with a logic high level of the second internal voltage VI2 to the pass circuit 254. The pass circuit 254 may output the internal deep power-down command IDPD received from the second level shifter 251 to the logic circuit 230. In response to the internal deep power-down command IDPD, the logic circuit 230 may control the semiconductor device 200 to enter a deep power-down mode.

In an embodiment, the semiconductor device 200 may receive the deep power-down command DPD from an external device in an operation mode other than the normal mode, and may process the deep power-down command DPD similarly to that described above for the normal mode.

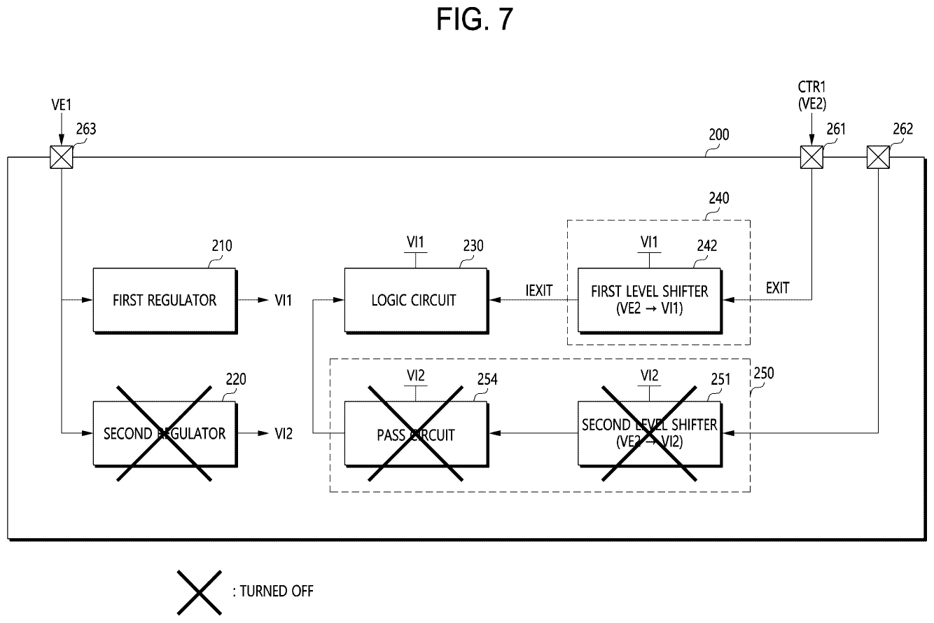

FIG. 7 is a diagram to illustrate how the semiconductor device 200 processes the exit command EXIT received in a deep power-down mode according to an embodiment of the present disclosure.

Referring to FIG. 7, in the deep power-down mode, the second regulator 220 may be turned off. Accordingly, the pass circuit 254 and the second level shifter 251 may also be turned off.

In the deep power-down mode, the exit command EXIT may be input as the first control signal CTR1 through the first pad 261 from an external device. The first level shifter 242 may receive the exit command EXIT from the first pad 261 with a logic high level of the second external voltage VE2, and may shift a voltage level of the exit command EXIT to output the internal exit command IEXIT with a logic high level of the first internal voltage VI1 to the logic circuit 230. In response to the internal exit command IEXIT, the logic circuit 230 may control the semiconductor device 200 to exit the deep power-down mode.

In summary, by turning off the second regulator 220 in a deep power-down mode, the pass circuit 254 might not generate leakage current. And, even if the second transmission circuit 250, including the pass circuit 254, is turned off in a deep power-down mode, the semiconductor device 200 may preferably exit a deep power-down mode by receiving the exit command EXIT through the first pad 261 and sending it to the logic circuit 230 through the first transmission circuit 240.

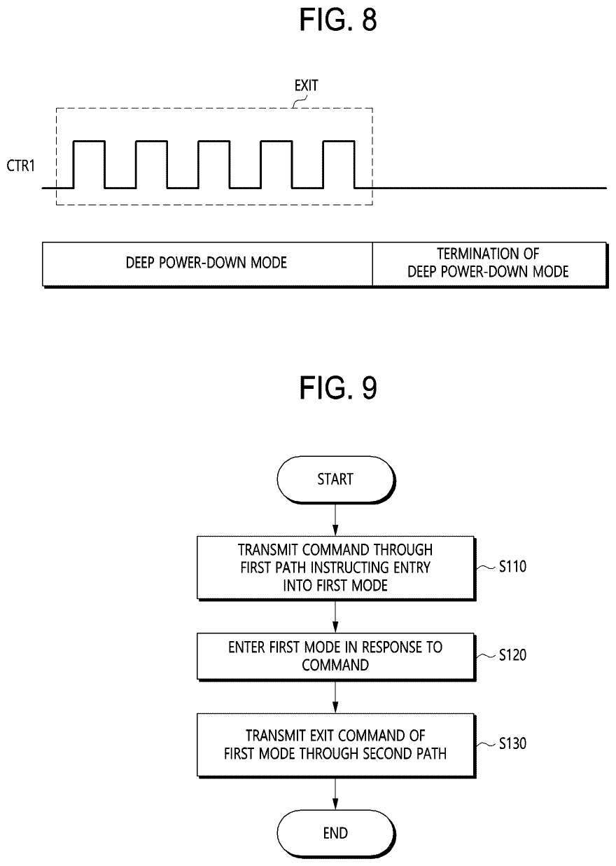

FIG. 8 is a waveform diagram of the exit command EXIT according to an embodiment of the present disclosure.

Referring to FIG. 8, the exit command EXIT may be transmitted in a predetermined pattern from an external device. For example, the exit command EXIT may be sent in a pattern of toggling five times. Thus, in the deep power-down mode, the semiconductor device 100 of FIG. 1 or the semiconductor device 200 of FIG. 5 may recognize the exit command EXIT in a predetermined pattern in the first control signal CTR1 and exit from the deep power-down mode.

FIG. 9 is a flowchart illustrating an operation method of a semiconductor device according to an embodiment of the present disclosure. The semiconductor device 100 of FIG. 1 or the semiconductor device 200 of FIG. 5 may operate based on the flowchart shown in FIG. 9. A first path described herein may be a path for transmitting a command through the second transmission circuit 150 of FIG. 1 or the second transmission circuit 250 of FIG. 5, and a second path may be a path for transmitting a command through the first transmission circuit 140 of FIG. 1 or the first transmission circuit 240 of FIG. 5.

Referring to FIG. 9, in operation S110, the semiconductor device may transmit a command to the logic circuit through the first path instructing entry into a first operation mode. The first operation mode may be a deep power-down mode. In an embodiment, the first operation mode may be an operation mode in which power consumption is reduced compared to a normal mode of the semiconductor device. The operation S110 may include shifting a voltage level of the command using an internal voltage supplied to the first path. The internal voltage supplied to the first path may be lower than an internal voltage supplied to the logic circuit.

In operation S120, the logic circuit of the semiconductor device may enter the first operation mode in response to the command. The operation S120 may include an operation where the logic circuit turns off a regulator that outputs an internal voltage to the first path using an external voltage. The operation S120 may include an operation where the logic circuit activates the first operation mode signal to enable the second path.

In operation S130, the semiconductor device may transmit an exit command of the first operation mode to the logic circuit through the second path in the first operation mode. The operation S130 may include shifting a voltage level of the exit command using an internal voltage supplied to the second path. The internal voltage supplied to the second path may be the same as the internal voltage supplied to the logic circuit.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure. Furthermore, the embodiments may be combined to form additional embodiments.

What is claimed is:

1. A semiconductor device comprising:
a first regulator configured to generate a first internal voltage;
a logic circuit configured to operate using the first internal voltage, and determine an operation mode; and
a first transmission circuit configured to transmit, using the first internal voltage, an exit command of the first operation mode externally input as a first control signal during the first operation mode to the logic circuit as an internal exit command.

2. The semiconductor device of claim 1, wherein the first operation mode is an operation mode in which power consumption is minimized, among a plurality of operation modes of the semiconductor device.

3. The semiconductor device of claim 1, further comprising at least one first pad configured to externally receive the first control signal.

4. The semiconductor device of claim 3, wherein the first transmission circuit comprises at least one first level shifter configured to shift a voltage level of the exit command using the first internal voltage to output the internal exit command.

5. The semiconductor device of claim 4, wherein the logic circuit is configured to generate a first operation mode signal that is enabled in the first operation mode, and
wherein the first transmission circuit further comprises at least one first switch configured to electrically connect the at least one first pad and the at least one first level shifter in response to the first operation mode signal.

6. The semiconductor device of claim 3, further comprising:
a second regulator configured to generate a second internal voltage; and
a second transmission circuit configured to transmit, using the second internal voltage, a second control signal externally input as a logic control signal during the second operation mode to the logic circuit.

7. The semiconductor device of claim 6, further comprising at least one second pad configured to externally receive the second control signal.

8. The semiconductor device of claim 7, wherein the second transmission circuit comprises:
at least one second level shifter configured to shift a voltage level of the second control signal using the second internal voltage to output a second internal control signal; and
a pass circuit configured to output, using the second internal voltage, the second internal control signal received from the second level shifter as the logic control signal.

9. The semiconductor device of claim 8, wherein the second transmission circuit further comprises at least one third level shifter configured to shift a voltage level of the first control signal using the second internal voltage to output a first internal control signal to the pass circuit.

10. The semiconductor device of claim 9, wherein the logic circuit is configured to generate a second operation mode signal that is enabled in the second operation mode, and
wherein the second transmission circuit further comprises at least one second switch configured to electrically connect the at least one first pad and the at least one third level shifter in response to the second operation mode signal.

11. The semiconductor device of claim 6, wherein the second control signal comprises a command instructing entry into the first operation mode.

12. The semiconductor device of claim 6, wherein the second operation mode is not an operation mode that consumes the least power among a plurality of operation modes of the semiconductor device.

13. A semiconductor device comprising:
a first regulator configured to generate a first internal voltage;
a second regulator configured to generate a second internal voltage;
a logic circuit configured to operate using the first internal voltage, and turn off the second regulator in a first operation mode; and
a transmission circuit configured to transmit, using the second internal voltage, a control signal externally input during a second operation mode to the logic circuit as a logic control signal.

14. An operating method of a semiconductor device, the operating method comprising:
transmitting a command instructing entry into a first operation mode to a logic circuit through a first path;
entering, by the logic circuit, the first operation mode in response to the command; and
transmitting an exit command of the first operation mode through a second path to the logic circuit.

15. The operating method of claim 14, wherein transmitting the command through the first path comprises shifting a voltage level of the command using an internal voltage supplied to the first path.

16. The operating method of claim 14, wherein entering the first operation mode comprises turning off, by the logic circuit, a regulator configured to supply an internal voltage to the first path using an external voltage.

17. The operating method of claim 14, wherein entering the first operation mode comprises enabling a first operation mode signal, by the logic circuit, to enable the second path.

18. The operating method of claim 14, wherein transmitting the exit command comprises shifting a voltage level of the exit command using an internal voltage supplied to the second path.

19. The operating method of claim 14, wherein an internal voltage used in the first path is lower than an internal voltage used in the second path.

20. The operating method of claim 14, further comprising:
externally receiving the command through a first pad; and
externally receiving the exit command through a second pad which is different from the first pad.
